(19) United States
(12) Patent Application Publication
(10) Pub. No.: US 2011/0244206 A1
(43) Pub. Date: Oct. 6, 2011

(54) EXTRUDED PLASTIC FILM FILLED WITH METAL PARTICLES, METHOD OF PRODUCTION AND USES THEREOF

(76) Inventors: Maria Cristina Penache, Chavanoz (FR); Alain Jean-Marie Marze, Chassieu (FR); Valérie Lacrampe, Vernaison (FR); Eric Jean Maitre, Marcy L'Etoile (FR); Pierre Casati, Lyon (FR)

(21) Appl. No.: 12/937,200

(22) PCT Filed: Apr. 8, 2009
(86) PCT No.: PCT/EP09/54272

§ 371 Date: Jun. 21, 2011

(30) Foreign Application Priority Data
Apr. 9, 2008 (FR) 0852394

(51) Int. Cl. B32B 5/16; B32B 27/14; B32B 27/36; B32B 27/32; B02C 19/00; B29C 47/88; B29C 47/06; B05D 1/30; B05D 3/00; C23C 16/513; C08K 3/08; C08K 3/22

(52) U.S. Cl. 428/220; 428/457; 428/500; 428/480; 241/3; 264/211.12; 264/210.1; 264/173.16; 427/420; 427/296; 427/569; 524/439; 524/430; 428/323; 428/328

(57) ABSTRACT

The present invention relates to a plastic film obtained by (co)extrusion or by a multilayer extrusion process.

The purpose of the invention is to supply a plastic film having useful properties, in particular of thermal behaviour, adhesion, linear tearability, and having a reduced production cost.

This film contains lamellar particles based on at least one metal and/or at least one metal oxide. It is obtained by the extrusion of a raw material constituted entirely or partly by a ground material from at least one coated film comprising at least one polyester and/or polyolefin film and at least one coating film based on at least one metal and/or at least one metal oxide.

The invention also relates to methods of manufacture of the raw material of the plastic film and of the plastic film and uses of said film.

Application in the field of packaging, decoration and heat treatments.

### FIELD OF THE INVENTION

The field of the invention is that of plastic films, in particular polyester and/or polyolefin films obtained by (co)extrusion.

These polyester and/or polyolefin films can in particular be coated films each comprising at least one polyester and/or polyolefin film and at least one coating film based on at least one metal and/or at least one metal oxide.

A subject of the present invention is a novel polyester and/or polyolefin film, containing particles of metal(s) or of metal oxide(s).

A further subject of the present invention is a method of manufacture of raw material of polyester and/or polyolefin film as well as a method of manufacture of said polyester and/or polyolefin film, containing particles of metal(s) or of metal oxide(s).

### GENERAL CONSIDERATIONS

### Technical Problem—Prior Art

Polyester films are very widely used owing to their well-known excellent properties of thermal stability, dimensional stability, chemical resistance and relatively high surface energy. Polyolefin films, in particular based on polypropylene, are particularly useful for their water vapour “barrier” properties and for their low cost which makes these materials very competitive relative to the polyesters.

When they are metallized, these polyester and/or polyolefin films are for example covered with a metallic layer (for example aluminium, copper, nickel, gold, silver, etc.) and are generally non-transparent. The nature of the metal and of the polymer used, as well as the thickness, vary according to the application.

The applications of these films are in particular food packaging, medical packaging and so-called industrial applications (e.g. electrical insulation, electronic components and protective films, optical films, films filtering a portion of the light spectrum, films for agriculture or the building industry) or for decorative purposes.

Regarding packaging, this can comprise packaging of food products from their site of manufacture/production up to when they reach the end user. These films are developed quite especially to ensure a barrier either to gases (oxygen, nitrogen, helium, water vapour, etc.) or to aromas. It may also be a packaging film for the cooking of foods in a microwave oven.

It can also be packaging for protecting various industrial products such as household electrical appliances, electronic items, etc.

In the case of decorating, these films are used for producing surfaces such as simulated wood for example. There are also applications in which these polyester and/or polyolefin films ensure scratch resistance.

To satisfy the ever changing requirements of the various applications, it is desirable for the manufacturers of films of this type to devise novel products.

Another problem facing said manufacturers relates to the economics of the industrial methods of manufacture (melting/extrusion). In this context, limitation of the film scrap rate and recycling of scrapped film is a preoccupation.

Japanese patent application JP-A-2194030 discloses a PET film that is resistant to abrasion and has good performance in terms of movement in the production line. This PET film is biaxially oriented and contains metal particles (e.g. Fe, Co, Ni, Pd, Sn, Cu, Ag, Au, Al or Pb) with diameter ranging from 0.01 to 3 μm, thus of substantially spherical shape, and present in a proportion from 0.005 to 5 wt. %. These particles form, on the surface of the film, bumps with a height comprised between 20 and 650 nm.

U.S. Pat. No. 3,516,841 describes a method for recycling a plastic-aluminium laminate for the manufacture of other products. The plastic given as an example is cellulose acetate-butyrate. It can also be PET. According to this method, the plastic-aluminium laminate is ground, sheared to separate the aluminium from the plastic. The ground-up mixture of plastic and aluminium is then subjected:

(i) either to a stage of separation of ground-up plastic/aluminium by sedimentation or filtration in an aqueous solution of CaCl₂ (with optional prior conversion of the Al to Al(OH)₃ by means of a solution of HgCl₂) or by filtration after adding the plastic/aluminium ground material to an aqueous solution of HgCl₂ for converting the Al to Al(OH)₃,

(ii) or to a stage of injection moulding from the ground-up mixture of plastic and aluminium.

The mixture of plastic/aluminium solid ground materials recovered at the end of separation (i) can serve as raw material for moulding, as in stage (ii).
This complex method requires heavy and expensive equipment. Furthermore, it does not disclose the manufacture of plastic, in particular polyester and/or polyolefin, films obtained by (co)extrusion.

French patent application FR 2 870 477 relates to a method of recycling by “compounding” extrusion of non-metallized polyolefin film waste. The method of recycling in question leads to the formation of granules composed of printed polyolefin films and a mineral filler. The product obtained is reused in the production of films of small or medium thickness. The polyolefin film wastes are converted to shreds, lamellae or flakes by processes of grinding and densification and are then fed into a twin-screw extruder, in which addition of mineral filler or other additives takes place.

More generally, the recycling of non-metallized plastic films is known, according to which the films are ground and the ground material obtained is transformed either by an agglomeration treatment in the pasty state, or by twin-screw vacuum extrusion. Sometimes the ground material is obtained with equipment operating on the “Vacurema” principle (extrusion from flakes, agglomerates or granules) using four stages of transformation integrated in the same machine:

1) compacting, sending the pasty product to the feed orifice of the screw extruder;

2) transport and start of extrusion in a double-diameter single-screw extruder;

3) degassing;

4) extrusion.

To date, the recycling of plastic films having a coating film, e.g. metallic, has not been used successfully in the manufacture of films. In fact, said metallized films have increased mechanical characteristics of rigidity and consequently the resultant ground product is coarse (fragments with a size of approximately ten micrometres in the plane of the coating) and quickly damage the blades of grinding mills. Moreover, this coarse ground material quickly clogs the polymer filters causing large production losses. Furthermore, this coarse ground material inevitably leads to film breakages on the film-making machines. Consequently, machine operating time is greatly reduced and the production costs are greatly increased. This goes against recycling and consequently this has curtailed the recycling of metallized plastic films in film manufacture.

There is therefore a gap in the recycling of films coated with a film of metal or metal oxide, for the re-manufacture of plastic films while avoiding the very serious drawbacks of the methods mentioned above, which make the costs of manufacture of such films prohibitive.

### OBJECTIVES OF THE INVENTION

One of the essential objectives of the present invention is in particular to fill the aforementioned gap by supplying a polyester and/or polyolefin film obtained by recycling of plastic films having a coating film of metal or of metal oxide, said film having a novel composition and novel characteristics.

Another essential objective of the present invention is to supply a polyester and/or polyolefin film obtained by recycling of plastic films having a coating film of metal or of metal oxide, said film including lamellar particles based on metal or metal oxide uniformly distributed in its bulk.

Another essential objective of the present invention is to supply a polyester and/or polyolefin film at greatly reduced production costs.

Another essential objective of the present invention consists of supplying a novel polyester and/or polyolefin film having particularly useful heat transfer properties for heat treatments of products packaged in said film, namely among other things cooking in a microwave oven, pasteurization, and sterilization.

Another essential objective of the present invention comprises supplying a novel polyester and/or polyolefin film having improved properties of adhesion in particular with respect to one or more metallic layers.

Another objective of the present invention consists of supplying a novel polyester and/or polyolefin film that is printable and/or sealable and/or peelable.

Another essential objective of the present invention consists of supplying a novel polyester and/or polyolefin film endowed with properties of improved linear tearability.

Another essential objective of the present invention consists of supplying a novel polyester and/or polyolefin film endowed with fire-resistant and in particular self-extinguishing properties.

Another essential objective of the present invention consists of supplying a novel polyester and/or polyolefin film obtained by (co)extrusion/melt or by a method of multilayer extrusion of a raw material constituted entirely or partly by a ground material from at least one coated film comprising at least one polyester and/or polyolefin film and at least one coating film based on at least one metal and/or at least one metal oxide.

Another essential objective of the present invention consists of supplying a novel method of manufacture of raw material or of precursor of a polyester and/or polyolefin film, containing lamellar particles based on at least one metal and/or at least one metal oxide.

Another essential objective of the present invention consists of supplying a novel method of manufacture of a polyester and/or polyolefin film containing lamellar particles based on at least one metal and/or at least one metal oxide.

Another essential objective of the present invention consists of supplying a simple and economical novel method of manufacture of a polyester and/or polyolefin film as well as the raw material thereof, containing lamellar particles based on at least one metal and/or at least one metal oxide.

Another essential objective of the present invention consists of supplying a novel method of recycling of waste of at least one coated film comprising at least one polyester and/or polyolefin film and at least one coating film based on at least one metal and/or at least one metal oxide.

Another essential objective of the present invention consists of providing novel applications of a polyester and/or polyolefin film containing lamellar particles based on at least one metal and/or at least one metal oxide, namely in particular the heat treatment of products (microwave cooking of foods, sterilization, pasteurization), packaging, preferably of foods, the decoration and/or protection of various substrates.

### BRIEF DESCRIPTION OF THE INVENTION

These objectives, among others, are achieved by the present invention, which relates, in a first aspect, to a polyester and/or polyolefin film obtained by (co)extrusion or by a multilayer extrusion process, characterized in that it contains lamellar particles based on at least one metal and/or at least one metal oxide and in that it is obtained by the extrusion of a raw material constituted entirely or partly by a ground material from at least one coated film comprising at least one polyester and/or polyolefin film and at least one coating film based on at least one metal and/or at least one metal oxide.

This novel polyester and/or polyolefin film filled with lamellar particles which are metallic and/or based on metal oxide(s), is obtained by a conventional melt/extrusion process. The lamellar particles are incorporated homogeneously in the bulk of the film.

This film therefore has a particular structure, composition and characteristics. In particular, said film is endowed with very good heat transfer properties, with a good barrier effect to light and to gases as well as good fire resistance (self-extinguishing). It has also been found to have good properties of linear tearability.

According to another of its aspects, the invention relates to a method of production of raw material (or precursor) of a polyester and/or polyolefin film that contains lamellar particles based on at least one metal and/or at least one metal oxide, in particular of the film as defined above. This raw material is constituted entirely or partly by a ground material from metallized film (e.g. polyester and/or polyolefin).

This method is characterized in that it comprises the following stages:
A. grinding, preferably of waste, of at least one coated film comprising at least one polyester and/or polyolefin film(s) and at least one coating film based on at least one metal and/or at least one metal oxide, so as to obtain flakes,
B. optionally the compacting of the flakes resulting from grinding to form agglomerates,
C. melting of the flakes or of the agglomerates resulting from compacting, preferably followed by filtration for removing the particles of metal and/or of at least one metal oxide, the largest dimension (L) of which is greater than or equal to 10 μm, preferably greater than or equal to 5 μm, and even more preferably greater than or equal to 3 μm,
D. transformation of the solidified mass into discrete elements—ground material—constituting the raw material, preferably into granules.

According to yet another of its aspects, the invention relates to a method of manufacture of a polyester and/or polyolefin film that contains lamellar particles based on at least one metal and/or at least one metal oxide, in particular the film as defined above, characterized in that it comprises the following stages:
A. grinding, preferably of waste, of at least one coated film comprising at least one polyester and/or polyolefin film(s) and at least one coating film based on at least one metal and/or at least one metal oxide, so as to obtain flakes,
B. optionally the compacting of the flakes resulting from grinding to form agglomerates,
C. melting of the flakes or of the agglomerates resulting from compacting, preferably followed by filtration for removing the particles of metal and/or of at least one metal oxide, the largest dimension (L) of which is greater than or equal to 10 μm, preferably greater than or equal to 5 μm, and even more preferably greater than or equal to 3 μm,
D. cooling/solidification of this molten mass,
E. transformation of the solidified mass into discrete elements, preferably into granules,
F. manufacture of the film by extrusion/melt of a mixture containing a quantity Qb (in wt. %) of said discrete elements, preferably of said granules, resulting from stage F,
G. cooling of the film resulting from stage F, preferably by means of an applying system and even more preferably, an electrostatic or air-knife applying system to a cooling drum;
said stage F and said stage G being implemented at the end of stage E (continuous mode) or after storage of the discrete elements, preferably granules, resulting from stage E (batch mode).

The invention also relates to a method of manufacture of a polyester and/or polyolefin film as defined above, characterized in that it also comprises the following stages:
H. longitudinal and transverse stretching of the film resulting from stage F or G,
I. heat-setting of the film resulting from stage H at a temperature above or equal to 150° C., more preferably between 180 and 250° C. and even more preferably at 240° C., when the film is constituted by polyester, and at a temperature above or equal to 120° C., more preferably between 130 and 200° C. and even more preferably at 150° C., when the film is constituted by polyolefin;
said stages H and I being applied at the end of stage G (continuous mode).

These simple and economical methods offer access to very useful possibilities for recycling and/or reuse of waste from metallized polyester and/or polyolefin film. In particular, these methods allow a considerable reduction in production costs.

These methods will also allow the recycling and/or reuse of waste of biodegradable and/or compactable metallized film.

According to yet another of its aspects, the invention relates to the use of the film according to the invention or of the film obtained by the method according to the invention, for the heat treatment of products, for packaging, or for decoration and/or protection of various substrates.

### DETAILED DESCRIPTION OF THE INVENTION

### The Particles

The lamellar particles used as filler in the film of the invention have carefully selected dimensional characteristics. Thus, they correspond to a form factor (F=L/e) defined as the ratio of the largest dimension (L) in the plane of the particle to its thickness (e):

10≦F≦1000, preferably 50≦F≦500.

For example (in μm):
0.01≦L≦500
preferably 0.1≦L≦100
and even more preferably 1≦L≦20;

and
0.001≦e≦1
preferably 0.01≦e≦0.5
and even more preferably 0.01≦e≦0.3, or even 0.01≦e≦0.3, e being for example of the order of 0.05.

The lamellar particles thus preferably have a sub-micrometric thickness (e). These particles, which are substantially flat, can have various shapes, in particular regular (rectangle, square, triangle, trapezium, oblong or ovoid) or irregular.

Preferably, these lamellar particles based on at least one metal and/or at least one metal oxide or based on metal oxides are arranged in an organized and uniform manner within the film. Thus, according to a significant characteristic, these lamellar particles are incorporated in the bulk of the film, not as clusters but as lamellae. More precisely and advantageously, the lamellar particles are substantially contained in one or more planes parallel to the faces of the film.

Preferably, aluminium particles are distributed homogeneously and randomly in the plane of the polyester film (e.g. PET) and/or polyolefin film (e.g. polypropylene).

In quantitative terms, the proportion Tx of lamellar particles (expressed in wt. %) is defined as follows:

10⁻³≦Tx≦10, preferably 10⁻²≦Tx≦5

The properties of the film vary as a function of Tx. Thus, the appearance of the film, the mechanical and/or optical properties, and the service properties, vary in correlation with said proportion, which itself is directly related to the quantity of ground material (Qb) contained in the raw material extruded for making the film. In the present disclosure it will also be stated by extension that said film contains a quantity Qb of ground material.

In qualitative terms, the metal of the lamellar particles is selected from the group comprising: aluminium, copper, nickel, silver, gold, etc., and their alloys, whereas the metal oxide of said lamellar particles is selected from the group comprising: the oxides of aluminium, of silicon and of metals of the aforementioned group and mixtures thereof. Aluminium and/or its oxides constitute one of the materials preferably used within the scope of the invention.

The Film and its Raw Material

According to a preferred embodiment of the invention, among other things, the polyester and/or polyolefin film derives at least some of its advantageous characteristics from the fact that it is obtained by the extrusion of a raw material constituted entirely or partly by a ground material from at least one coated film comprising at least one polyester and/or polyolefin film and at least one coating film based on at least one metal and/or at least one metal oxide.

Preferably, the coated film from which the ground material is produced comprises coated film to be recycled, preferably waste coated film.

This touches on a recurring problem in the manufacture of polymer films, namely the recycling of the appreciable quantities of waste film. In this particular case, we are concerned e.g. with waste of films coated with a layer of metal or metal oxide, commonly called metallized polymer films. In practice, it may for example be a question of recycling the waste produced during the manufacture of polyester films (PET) and/or polyolefin films (e.g. polypropylene) each coated on one side with a thin coating film of aluminium obtained by vacuum evaporation. Such recycling makes it possible to lower the cost price of polymer films considerably, whether or not they themselves are metallized.
The coatings of the films to be recycled that form the raw material of the films according to the present invention are for example thin inorganic coatings, preferably obtained by a vacuum process, which in addition to modification of the surface properties of the film, add a function (for example gas barrier). A coated film according to the invention is therefore a film covered with a surface coating film, said coating film having a thickness clearly less than that of the substrate on which it is located, in this case the film. Preferably, this coating film is sub-micrometric. This coating film, which is substantially thinner than the substrate, cannot be machined on its own as it is very fragile. Consequently, it is not possible to use it without the substrate (film) for processing. Thus, the coating of the film to be recycled that can form the raw material of the films according to the invention differs from a “laminate”, which corresponds to an assemblage of different layers each having their own physical existence. It is obtained by technologies such as pasting, laminating, extrusion coating, complexing, etc.
According to a preferred characteristic of the invention, the “metallized” coated film from which the ground material is produced comprises a layer of polyester and/or polyolefin film of the same kind as the polyester and/or polyolefin film in question.
This preferred but non-limitative hypothesis is what will be envisaged as an example in the more detailed description of the method according to the invention.
The “metallized” coated film is for example a PET film coated on one side with a thin coating film of aluminium obtained by vacuum evaporation.
It was possible to develop this preferred embodiment of the invention in particular on the basis of the specific technological means that are comprised in the method according to the invention, described in detail below.

Moreover, this film according to the preferred embodiment of the invention is obtained by the extrusion of a raw material comprising a quantity of ground material (Qb in wt. %) such that Qb≦100. In this case, the raw material of the film according to the invention is supplemented with another raw material different from the ground material and comprising for example polyester and/or polyolefin and/or another polymer, preferably free or almost free (e.g. less than or equal to 0.1% w/w) from metal particles. For extrusion, these raw materials of the film are generally in the form of granules.

Two classes of film (classes 1 and 2) have been identified within the scope of the invention, depending on the Qb of the raw material extruded to manufacture the film.

Class 1 is such that:
20<Qb≦100
preferably 25≦Qb≦99
and even more preferably 30≦Qb≦95.
   This class 1 is in particular characterized by the following properties: improved linear tearability, decorative appearance, improved adherence of a coating, suitability for microwave cooking.
   Class 2 is such that:
10⁻¹≦Qb≦20
preferably 1≦Qb≦20
and even more preferably 2≦Qb≦20.
   This class 2 is in particular characterized by the following properties: mechanical properties identical to the films without addition of ground material, good transparency, reduced costs of manufacture.

The film according to the invention can be constituted by several co-extruded layers (total number of layers=2 to 5 for example) or can be obtained by a multilayer extrusion process (total number of layers=2 to 10,000 for example).

It is possible to vary the percentage of metal particles, and therefore the percentage of starting ground material Qb, in some or all of these layers.
Moreover, the percentage of metal particles, and hence the percentage of starting ground material Qb, can be different from layer to layer. In this way the percentage of metal particles is varied over the thickness of the film. Certain layers of these multilayer films may possibly not contain particles (Qb=0% in the starting extruded raw material for making the layer in question).

This quantity Qb is not the loading of lamellar particles of the film according to the invention. In fact, the ground material is constituted partly by metal particles and partly by the polymer (preferably polyester and/or polyolefin) forming the recycled coated (“metallized”) film. The total loading of lamellar particles in the film is easily accessed for example from data on the surface area and thickness of the metal and polymer of the recycled waste. A possible alternative method for quantification of the metal loading is measurement by X-ray fluorescence.

According to a significant characteristic of the invention, the polyester and/or polyolefin film is biaxially stretched. According to a variant of the invention, the film can be isotropic biaxially stretched (properties similar in all directions) or tensilized biaxially stretched (specific properties in one direction, particularly the machine direction) or balanced biaxially stretched.

According to another significant characteristic of the invention, the polyester and/or polyolefin film has a thickness (e) between 3 and 350 microns, even better in practice between 8 and 50 μm, preferably between 8 and 36 μm, and even more preferably between 4 and 23 μm. The polyester film preferably has a thickness of 12 μm, and the polyolefin film preferably has a thickness of 18 μm. The film according to the invention can be coated or uncoated, i.e. it either has or does not have at least one coating on at least one of its faces. Coating means for example a layer of polymer (for example of polyester and/or polyolefin) or a layer based on a non-polymeric material, for example a metal or a metal oxide.

Advantageously, said coating is obtained by coextrusion, coating, varnishing, extrusion coating, hot melt coating, vacuum evaporation or any other method of vacuum deposition such as chemical vacuum deposition.

In one embodiment, the coating is of a metallic nature and the adhesion of said coating on the polyester and/or polyolefin substrate film with filler of lamellar particles (adhesion measured according to the AIMCAL recommendations TP-105-92 (Metallizing Technical Reference published by Association of Industrial Metallizers, Coaters and Laminators) is greater than or equal to 0.05 N/38 mm, preferably greater than or equal to 0.1 N/38 mm, and even more preferably greater than or equal to 0.2 N/38 mm.

It has in fact been found that coatings, of whatever kind, adhere particularly well to the film according to the invention.
This property of adhesion is more pronounced in the films of class 1 as defined above. The higher the value of Qb, the more the property of adhesion, in particular with respect to metals, of the film according to the invention is reinforced. For example, the adhesion strength of an aluminium coating film to a PET film with filler of lamellar particles of which the Qb=60 is improved by a factor of 4 relative to that obtained between the same coating film and a PET film without lamellar particle filler.

For further improvement of these properties of adhesion, it can be envisaged that at least a portion of the surface of the film according to the invention is subjected to an electric discharge treatment of the corona type and/or to a treatment of the plasma type.

Said treatment of the corona type is a corona discharge under ambient air at atmospheric pressure or under gases at high partial pressures, preferably between 100 mbar and 3000 mbar, even more preferably at atmospheric pressure.
Said treatment of the plasma type can be carried out by means of plasma discharge under vacuum, at low partial pressures, preferably between 10⁻⁵ mbar and 1 mbar, even more preferably between 10⁻³ and 10⁻¹ mbar.

The film with lamellar particle filler according to the invention can be of polyester and/or of polyolefin. The polyesters and the polyolefins in question are homopolymers or copolymers. They can be co(polyester(s))(polyolefin(s)).

Polyester Film

The polyester films more especially envisaged are for example aromatic polyesters and in particular polyethylene terephthalate PET (e.g. biaxially oriented) or polyethylene naphthalate (PEN) or polybutylene terephthalate (PBT).

When the polyester film is an aromatic polyester, it is preferably an essentially linear aromatic polyester, obtained from an aromatic dibasic acid or from an ester derived from said acid, and from a diol or from an ester derived from said diol.
Advantageously, the polyester film used is biaxially oriented.
The polyester constituting the substrate film can be selected from the polyesters that are usually used in order to obtain biaxially oriented semi-crystalline films. They are film-forming linear polyesters, crystallizable by orientation and obtained in the usual way from one or more aromatic dicarboxylic acids or derivatives thereof (esters of lower aliphatic alcohols or halides for example) and one or more aliphatic diols (glycols).
As examples of aromatic acids, there may be mentioned the phthalic, terephthalic, isophthalic, 2,5-naphthalenedicarboxylic, and 2,6-naphthalenedicarboxylic acids. These acids can be combined with a smaller quantity of one or more aliphatic or cycloaliphatic dicarboxylic acids, such as adipic, azelaic, tetra- or hexahydroterephthalic acids.
As non-limitative examples of aliphatic diols, there may be mentioned ethylene glycol, 1,3-propanediol, 1,4-butanediol. These diols can be combined with a smaller quantity of one or more aliphatic diols that are more condensed with respect to carbon (neopentylglycol for example) or cycloaliphatic diols (cyclohexanedimethanol).
Preferably, the film-forming crystallizable polyesters are alkylenediol polyterephthalates or polynaphthalenedicarboxylates, and in particular polyethyleneglycol terephthalate (PET) or 1,4-butanediol or copolyesters comprising at least 80 mol. % ethylene glycol terephthalate units. Advantageously, the polyester is a polyethylene glycol terephthalate of which the intrinsic viscosity measured at 25° C. in ortho-chlorophenol is comprised between 0.6 and 0.75 dl/g.
The biaxially oriented polyester films are, for example:
either constituted by polyethylene terephthalate,
or they are mixtures, or not, of polyethylene terephthalate copolyesters containing cyclohexyl dimethylol units instead of the ethylene units (see U.S. Pat. No. 4,041,206 or EP-A-0408042),
or are composed of mixtures, or not, of polyethylene terephthalate copolyesters with a polyester portion having isophthalate units (see patent EP-B-0515096),
or are constituted by several layers of polyesters of different chemical natures, as described previously, obtained by coextrusion.
   Specific examples of aromatic polyesters are in particular polyethylene terephthalate (PET), polyethylene isophthalate, polybutylene terephthalate, poly-(dimethyl-1,4-cyclohexyleneterephthalate) and polyethylene-2,6-naphthalenedicarboxylate. The aromatic polyester can be a copolymer of these polymers or a blend of these polymers with a small quantity of other resins, for example and without being limitative, polybutylene terephthalate (PBT). Among these polyesters, polyethylene terephthalate (PET) and polyethylene-2,6-naphthalenedicarboxylate (PEN) are particularly preferred as they offer a good balance between physical properties, mechanical properties and optical properties. The polyesters can contain (at least at the surface) a filler C′ as required, different from the lamellar particles, such as for example a filler for limiting the adherence between the turns of the film when it is wound in a roll. This filler C′ is advantageously incorporated in the polyester in order to modify its surface properties. As examples of fillers C′ that are known as lubricants for polyester film, there may be mentioned calcium carbonate, calcium oxide, aluminium oxide, titanium dioxide, kaolin, silica, zinc oxide, carbon black, silicon carbide, tin oxide, particles of cross-linked acrylic resin, particles of cross-linked polystyrene resin, particles of cross-linked melanin resin, particles of cross-linked silicone resin or similar. Preferably, fillers C′ of the silica and/or carbonate type are used. The particles of filler C′ described above can have an average diameter between 0.05 and 60 microns and are preferably present in a quantity comprised between 0 and 140,000 parts per million by weight relative to the total mass of the (e.g. aromatic) polyester and more particularly between 0.5 and 6 microns and are preferably present in a quantity between 200 and 1500 parts per million by weight relative to the total mass of the (e.g. aromatic) polyester. If a film of high transparency is desired, it is preferable to avoid massive incorporation of filler. Moreover, in addition to filler C′, other additives can be added to the polyesters if required, namely in particular a dye, an antistatic agent, an optical brightener, an antioxidant, an organic lubricant, an anti-UV additive or fireproofing additive, a catalyst, or any other additive. The anti-UV additive can be selected from several examples of known products such as those described in the work “Additives for plastics on book, John Murphy, 2^{nd} Edition 2001, Elsevier Advanced Technology”. As examples of anti-UV additives, there may be mentioned those of the family of antioxidants or absorbers such as the benzophenones, the benzotriazoles, the benzoxazinones and the triazines; and those of the family of “Hindered amine light stabilizers” (HALS), alone or in combination with antioxidants. These anti-UV additives serve for countering the effects of UV and oxygen on polyester films.

Polyolefin Film

The polyolefin films more especially envisaged are for example aliphatic polyolefins such as polyethylene or polypropylene or aromatic polyolefins such as polystyrene.

Films of aliphatic polyolefins are preferably made from mono-α olefin polymers comprising 2 to 8 carbon atoms and in particular 2 to 4 carbon atoms per molecule. The polymer can be a homopolymer or a copolymer of two or more of the olefins, for example the following olefins: ethylene, propylene, 1-butene, hexene and 4-methylpentene-1.

The polypropylenes are widely used in packaging and in various industries: automobile, household electric appliances, sanitary engineering, textiles, furniture, etc. Certain properties of the polypropylenes are useful for the manufacture of films, namely their high melting point (130 to 170° C.) and their high Young's modulus (70 to 1600 MPa), the possibility of obtaining products with exceptional mechanical strength (300 to 400 MPa) by uniaxial or biaxial orientation, the possibility of obtaining polypropylenes with high impact strength at low temperatures and at ambient temperature as well as products filled or reinforced with glass fibres.
The polypropylenes can be:
homopolymers that have maximum isotacticity (92 to 99%), maximum crystallinity, high melting point and high Young's modulus but low impact strength,
random copolymers generally with 1.5 to 7 wt. % of polymerized ethylene, which have better heat sealing properties and higher impact strength than the homopolymers but have a lower Young's modulus, a lower melting point and a lower density,
block copolymers for which the proportion of elastomer in the product varies from 10 to 35 wt. %, the impact strength is high even at low temperature, but the Young's modulus and the melting point are below those of the homopolymers.
   The properties of the polypropylenes, whether they are homopolymers or copolymers, depends on their crystallinity, their molecular weight, their molecular distribution as well as their chemical composition.

A material that is particularly suitable for the films of the present invention is polypropylene, particularly a propylene polymer with high molecular weight that is stereoregular and predominantly crystalline. As a variant, a propylene copolymer with more than 20% of another olefin (for example ethylene) can be used for the present invention.

Polypropylene films can have uniaxial or biaxial orientation. In general, for biaxially oriented films, the polypropylene is extruded (between 180 and 300° C.) through a slot die, then cooled on a cold roll. Next, the film is heated to a temperature below its melting point and then stretched successively in the direction of extrusion and in the transverse direction. The degree of stretching varies from 5 to 7 in the two directions. The breaking strength of this type of film increases considerably (approximately 400 MPa) whereas its elongation at break becomes very low, from 10 to 30%. A biaxially oriented polypropylene film is in most cases transparent.
For industrial applications, polypropylene has an isotacticity of the order of 92 to 98%, which means that the “isotactic” polymer also has some syndiotactic or atactic sequences. The polypropylenes used for the films according to the present invention generally have an isotacticity of approximately 90%, which gives them good properties of tensile strength, and resistance to the stress and deformation imposed by the machines for forming the products. Preferably, for better strength and better processing, the polypropylenes used are isotactic polypropylenes that have high crystallinity between approximately 95% and approximately 98%. The impact strength of polypropylene depends on its crystallinity, molecular weight and the composition of the product. A polyolefin that is particularly suitable for the present invention and is preferred is isotactic polypropylene with a density between 0.86 and 0.92 g/cm³ and a melt flow rate from 1 to 15 g/10 min as determined according to ASTM D1238 (conditions 230° C. and 2.16 kg).
The polypropylenes used can also be resins with high isotacticity (preferably above 90%) and high crystallinity. They can also be treated preferably under an atmosphere of CO₂, N₂, or a mixture thereof.
Examples of commercial polypropylenes that are highly crystalline and suitable for the production of strong oil-based films are FINA® 3270, EXXON® 1043N, HUNTSMAN® 6310 and AMOCO® 9117. These resins preferably have a melting point at approximately 163-167° C., a crystallization temperature of approximately 108-126° C., a heat of fusion of approximately 86-110 J/g, and a heat of crystallization of approximately 105-111 J/g.
The polypropylene film can also optionally contain at least one hydrocarbon resin additive. Although it is not indispensable, addition of this additive aids biaxial orientation of the film by offering a wider processing window, in terms of processing temperatures for the machine direction (MD) and in particular for orientation in the transverse direction (TD).
Polypropylene films can be metallized under vacuum and, under certain conditions, can be metallized by electroplating, after etching in a sulphochromic bath or plasma treatment for example.

Production of the Ground Material Forming Some or all of the Raw Material of the Film According to the Invention and Manufacture of the Amorphous or Biaxially Stretched Film According to the Invention

As explained above, the film according to the invention is obtained by (co)extrusion or by a multilayer extrusion process from a raw material constituted entirely or partly by a ground material from a polyester and/or polyolefin film coated with a metallic coating film (e.g. within the scope of recycling of waste of this type of metallized film).

The invention thus relates on the one hand to the production of the ground material forming some or all of the raw material and on the other hand the manufacture of an amorphous or biaxially stretched film according to the invention. As presented below, stages A to E make it possible to produce discrete elements, preferably granules, which can be stored before being used in the manufacture of the film according to the invention (batch mode). These discrete elements, preferably said granules, are intermediates that can be marketed as such, as raw material (or precursor) of the film according to the invention. Starting from these intermediates, stages F and G make it possible to obtain an amorphous film according to the invention. Stages H and I, which are carried out after stages F and G, allow the manufacture of a biaxially stretched film according to the invention.
In batch mode, stages A to E are carried out, the ground material is stored for a certain length of time, then stages F and G, or also stages H and I, are carried out.
In continuous mode, stages A to G, or even A to I, are carried out successively.

The details of stages A to I are presented below.

Stage A:

Grinding is carried out according to the following method: the torched film(s) and/or selvedges is (are) fed into a rotating-blade grinding mill which cuts them up into flakes. It is preferable to use a grinding mill with metal or ceramic blades (even more preferably ceramic) for its robustness with respect to the films.

Stage B:

The flakes resulting from grinding are compacted in a mechanical agglomerator which gives a densified product having approximately a twisted and spongy appearance.

Stages C, D and E:

Melting of the polymer fraction of the agglomerates resulting from compacting is preferably carried out by vacuum extrusion. In certain cases, the agglomeration stage is not necessary and melting is carried out directly on flakes.

Melting is carried out in integrated extruders for simultaneously improving the compacting of the polymers and for remelting them under vacuum under very good processing conditions (temperature, absence of oxidative degradation, etc.). A rod die can be used for extruding polymer threads, which are cooled rapidly in water afterwards and then cut into granules.
This machine preferably has specially designed filtration equipment to permit the processing of polymers with metal particles.
The filtration equipment is intended to remove the particles of metal and/or of at least one metal oxide, the largest dimension (L) of which is greater than or equal to 10 μm, preferably greater than or equal to 5 μm, and even more preferably greater than or equal to 3 μm.
This equipment contains for example a special Vacurema® filter, of controlled mesh, preferably of approximately 30 μm, of the multipore or grille mesh type or in certain cases microporous.
The specific technological means are for example, without being limitative:
a recycling line of the EREMA® type with a capacity of at least 2000 kg/hour,
a filtration set of medium class with automatic changing,
a rod die,
a RIETER® granulator,
a gooseneck dryer,
a silo for storing the granules.

Stage F:

The polyester and/or polyolefin film is obtained by a melt extrusion process, in which granules of polymer (polyester, preferably PET, and/or polyolefin) and polymer/lamellar filler granules obtained in C, D and E are fed into an extruder. Other additives and/or polymers, with or without filler, can be included in the composition of the mixture.

The mixture of granules is then extruded in the molten state through a die (preferably a slot die) as a thick, amorphous film.

Good particle distribution results in particular from good homogenization of the melt-extruded mass. Said homogenization can for example be optimized by the installation, on the film-making line, of at least one polymer filter of suitable structure, mesh and filtration area.

Stage G:

Stage G consists of cooling the thick film obtained in stage F, for example to 20° C., and applying it, by any suitable known means, such as electrostatic applying in the case of polyester and air-knife applying in the case of polyolefins, to a cooling drum, so as to form an amorphous film.

Stages H and I:

The film obtained after stage F or G is then advantageously subjected (stage H) to two-dimensional stretching, which can be longitudinal at first, for example MD (degree LS 3.0) followed by transverse stretching (degree TS 3.5). The degree of planar stretching (defined as the product of the degree of longitudinal stretching and the degree of transverse stretching, regardless of the order thereof) is for example comprised between 1 and 20, usually greater than 12 for polyester. For polyolefins, the degree of planar stretching is much greater, typically greater than 40 with a degree of longitudinal stretching LS 4.5 and a degree of transverse stretching TS≦10.

The stretching sequences can be different depending on the machines used without affecting the properties obtained according to the invention. For example, it may be useful to use so-called reverse-sequence machines or multistep machines, machines with alternating sequences or machines for simultaneous stretching, etc.

For the polyester, the stretching temperature is for example comprised between the glass transition temperature Tg and a temperature equal to at most Tg+60° C. both in the longitudinal direction and in the transverse direction.

Longitudinal stretching is carried out for example with a factor of 3 to 6 and transverse stretching for example with a factor of 3 to 5.
As an example, for PET, heat-setting (I) is carried out between 180 and 250° C. (e.g. 240° C.) for 1 to 60 seconds for example and then at a lower temperature in order to stabilize the film.

Variants of the Method

According to one variant, the metal particles are incorporated in the polymer at least partly in free form, i.e. not included in a polymer matrix resulting from the utilization (waste recycling) of metallized polymer.

According to another variant, the film according to the invention can be of simple structure or coextruded αβ, αβα or αβχ or even of more complex structure of the multilayer type (the symbols α, β and χ corresponding to layers of a different nature and/or composition).

According to yet another variant, the film according to the invention can easily be laminated by thermal bonding and/or bonding with adhesive to a very large number of other substrates, in particular including sheet metal, for example steel, plates or sheets of glass or other glass-like polymers or cardboard and other materials.

The Applications of the Film According to the Invention

One of the possible uses of the film according to the invention relates to the heat treatment of products, said treatment being selected advantageously from the group of treatments comprising:
sterilization,
pasteurization,
cooking or reheating of foods in a microwave oven,
reheating or cooking of food products with steam, etc.
   These thermal uses relate more especially to the films of class 1 (cf. above) in which the quantity of ground material (Qb in wt. %) is greater than 20.
   The optical density of the films of class 1 is for example between 0.1 and 0.5. This permits improved and quicker microwave cooking of food products packaged using this film with lamellar particle filler and endowed with useful heat transfer properties and partial filtering of electromagnetic waves. This is the application commonly called “film susceptor”. The food products in question are in particular popcorn, pizzas, meats (e.g. poultry). It is possible to cook these products and obtain the browning corresponding to conventional cooking. Reheating is of course optimized too. These foods that are cooked or reheated in the microwave oven in this way can be frozen or non-frozen foods. These films can reduce the usual cooking time for example by a factor greater than 10 while preserving the taste characteristics obtained with a conventional oven.
   These films can also be used for the heat treatment of various products, in particular food products, as they are extremely resistant to high temperatures (e.g. above 120° C.). The heat treatments envisaged are, among others: sterilization, pasteurization.

Another use of the film according to the invention is packaging, preferably of foods. This packaging film, in particular for foodstuffs, in fact forms an opaque barrier to light and to gases, which contributes to good preservation of foods. The films according to the invention have food preservation properties because, being metallized, they constitute an opaque barrier to light (UV) and to gases (water vapour, oxygen, etc.) and thus prevent oxidation of food products.

In this particular application, the film according to the invention is preferably a film of class 2, with Qb=2 to 20% (wt. %). The properties of such a film are similar to those of a film comprising a layer of the same polymer and a metallic coating or one based on metal oxide(s), namely for example an aluminium-metallized PET polyester film.

The use of the film according to the invention in packaging leads to significant gains with regard to the production cost relative to a standard metallized (e.g. PET) film.

Biaxially oriented films based on polypropylene are used in particular in the field of packaging of food products such as snacks, biscuits, and chocolate-coated bars as they have good properties of sealing, protection by barrier effect and tearability.

Yet another use of the film according to the invention is the decoration and/or protection of various substrates. The latter can be among other things sheet metals, panels of wood or any materials.

One embodiment of the film according to the invention in which it is metallized on one of its faces can be advantageous in the field of decoration. In fact in this case, one of the faces of the film is glossy, the other is matte and gives a brushed steel effect (differences in gloss from one face to the other).

Yet another use of the film according to the invention is the fire protection of various substrates. In certain embodiments, the film can make the substrates self-extinguishing.

According to an advantageous embodiment of the invention, the film in question is printable. Owing to the presence of a quantity Qb of ground material (in wt. %) between 70 and 90, preferably of the order of 80, the surface tension of this film increases. In the case of polyester it is greater than or equal to 48 mN/m, preferably between 48 and 60 mN/m, and even more preferably approximately 50 mN/m (for example typical value of 54 mN/m). It should be noted that as this phenomenon is a surface property, it can be obtained by coextrusion, a multilayer process, extrusion coating, hot melt coating, etc.

The fact that the film according to the present invention is “sealable” and/or “peelable” (i.e. detachable from a substrate of various materials, for example plastic or metal), and tearable, it can have numerous applications.

The film according to the present invention can be sealable on itself and/or on other plastics such as APET, CPET, PVC, PS, etc., metallic materials and/or vitreous materials.

It is to be noted that as the Qb of the film according to the invention increases, the film tears more easily without “saw teeth”.

The films according to the present invention can be used for applications with heating by eddy currents. These eddy currents are induced currents that arise for example in a conductor moving in a constant magnetic field or also in an immobile metallic solid subjected to a variation in magnetic field. They are a consequence of magnetic induction.

The eddy currents that are set up in the immobile metallic article thus cause heating by the Joule effect.

Examples of manufacture and evaluation of the film according to the invention will give a better understanding of the latter and all of its advantages.

Description of the Tables
Table 1: Characterization of various batches of re-granulated metallized PET.
Table 2: Microwave cooking test in the presence of a film containing ground material.

### DESCRIPTION OF THE DRAWINGS

FIGS. 1a to 1e show four photographs of the film according to the invention

FIG. 1a: view with a transmission light microscope (magnification ×1100) in the XY plane;

FIG. 1b, 1c, 1d: transverse sections (Z plane), viewed with a transmission electron microscope (magnification ×5600, ×24000, ×84000 respectively);

FIG. 1e: view with a transmission electron microscope in the XY plane of a metal particle after dissolution of the polyester.

FIG. 2 is a graph showing the aluminium content (Al), in wt. %, measured from the ash content and the content of aluminium oxide (Al₂O₃), in wt. %, measured by X-ray fluorescence as a function of the concentration of ground material (Qb, in wt. %) contained in the films.

FIG. 3 is a graph showing measurement of optical density as a function of the concentration of ground material (Qb, in wt. %) contained in the films.

FIG. 4 is a graph showing measurement of haze as a function of the concentration of ground material (Qb, in wt. %) contained in the films.

The FIGS. 5a and 5b are graphs showing respectively the whiteness index and L* as a function of the concentration of ground material (Qb, in wt. %) contained in the films.

FIG. 6 is a graph showing the measurement of gloss as a function of the concentration of ground material (Qb, in wt. %) contained in the films.

FIG. 7 is a graph showing the melt resistivity (MΩm) as a function of the concentration of ground material (Qb, in wt. %) contained in the films.

### EXAMPLES

### I—Method of Production of PET Films Filled with Lamellar Particles of Aluminium

1. Method of Preparation of the Ground Material Based on Metallized Polyester

After being ground in an ALPINE® grinding mill from HOSOKAWA® (stage A), PET films metallized with aluminium (CLARYL® range from TORAY®) are processed on a machine of the VACUREMA® type from EREMA®.

Next, the films reduced to flakes are compacted and agglomerated in a compactor at 172° C. (stage B). Then the agglomerates are melted at 280° C. (stage C). The molten mass is then cooled and solidified in a stream of water at ambient temperature (stage D) by means of equipment associated with the VACUREMA® machine, with the brand-name RIETER®. Said cooled mass is cut at ambient temperature into granules by the device downstream of the RIETER® equipment (stage E).
The characteristics and operating conditions of grinding, agglomeration and extrusion (stages A-E) are as follows:

### Characteristics and Operating Conditions of the Compactor

Motor power: 71 KW
Compacting speed: 145 rpm
Machine loading: 61%
Level of vacuum: 36 mbar
Temperature of the granules in the compactor: 172° C.
Temperature of the zone at the level of the filling hole of the extruder: 196° C.

### Condition of Vacuum Extrusion

Flow rate: 946 kg/hour
Screw speed: 64 rpm
Machine loading: 55%
Level of vacuum: 20 mbar
Filtration is ensured by 4 metal filters with a “cut-off” of 35 microns. Neither filter clogging nor deposits are found on dismantling.
The ground material that is to be used for making the films as described above is analysed by X-ray fluorescence according to an in-house method usually used for the characterization of PET. The measurements prove that aluminium is present in the re-granulated material (see Table 1). The viscosity index is measured according to ISO 1628-5 and the results are given in Table 1.

TABLE 1
Characterization of the various batches
of re-granulated metallized PET.

| PET | | | | | | | | |
|---|---|---|---|---|---|---|---|---|
| Aluminium | | | | | | | | |
| Granules | VI | X-ray Fluorescence (ppm) | | | | | | |
| Tests | (dl/g) | Ca | P | Sb | Mg | SiO₂ | Ti | Al |
| 1 | 0.559 | 41 | 46 | 165 | 53 | 727 | 1 | 8066 |
| 2 | 0.558 | 28 | 48 | 167 | 50 | 706 | 1 | 7016 |
| 3 | 0.562 | 32 | 48 | 165 | 44 | 723 | 1 | 7833 |
| 4 | 0.57 | 42 | 49 | 167 | 37 | 745 | 1 | 8024 |
| 5 | 0.569 | 42 | 47 | 163 | 48 | 754 | 1 | 8040 |

2. Preparation of PET Films Containing Said Ground Material

Next, the granules thus obtained, called ground material above, are extruded mixed with other polymers in the film-making machine (stage F) in order to produce new films of polyester filled with lamellar particles of aluminium with percentages of ground material Qb less than or equal to 100 (in wt. %).
The various mixtures based on PET and ground material are homogenized in the granulated state and are then extruded in the molten state through a slot die as a thick film, which is cooled by electrostatic applying to a cooling drum at 20° C. (stage G), so as to form an amorphous film.

3. Preparation of Biaxially Oriented PET Films Containing Said Ground Material

Biaxially oriented PET films containing ground material are produced according to the conditions for preparation of the film usually used in the field of packaging. For reasons of processability, inorganic fillers are incorporated at a concentration usually below 0.1%. In these examples, the percentages of ground material Qb incorporated vary in the mass of the films comprising an extruded layer. In these examples, a polyethylene terephthalate PET is used that has a viscosity index of 0.64 dl/g (measured according to standard ISO 1628-5) and contains 0.1 wt. % of a filler constituted by particles of silica having a median diameter by volume d₅₀ of approximately 3.5 μm. In these examples, the ground material used has a viscosity index (measured according to the same standard mentioned above) of 0.56 dl/g. The ground material is in this case derived from a method of recycling of films of the CLARYL® type comprising a PET film coated on one side with a thin coating film of aluminium obtained by vacuum evaporation.
The various mixtures based on PET and ground material are homogenized in the granulated state and are then extruded in the molten state through a slot die as a thick film, which is cooled by electrostatic applying to a cooling drum at 20° C. (stage G), so as to form an amorphous film. The film thus obtained is then subjected to longitudinal stretching MD (degree LS 3.0) followed by transverse stretching (degree TS 3.5) (stage H). The degree of planar stretching (defined as the product of the degree of longitudinal stretching and the degree of transverse stretching, regardless of the order thereof) is 10.5. The biaxially stretched film (having a thickness of 12 μm in all the examples) is then subjected to heat-setting at a temperature above 215° C. (stage I). Finally the films are subjected to various assessments.

4. Form, Distribution and Dimensions of the Particles in the Biaxially Oriented Filled Films—Observations with the Microscope.

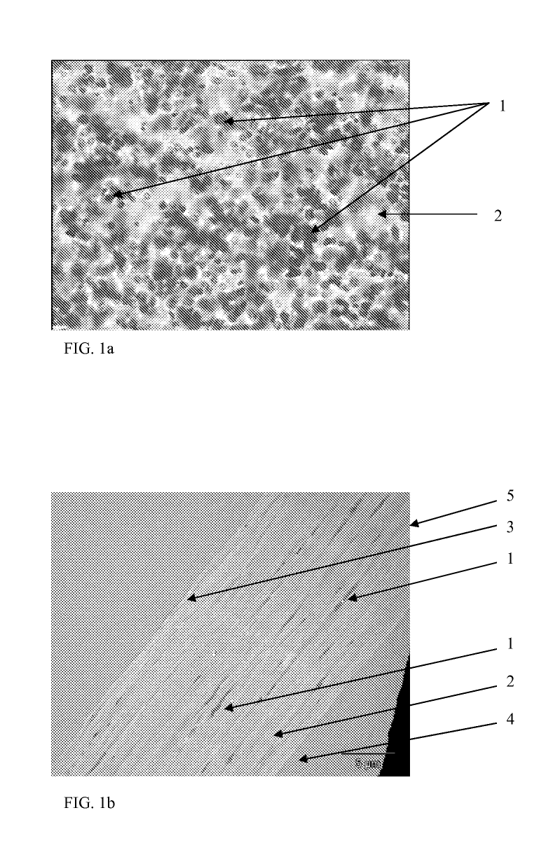

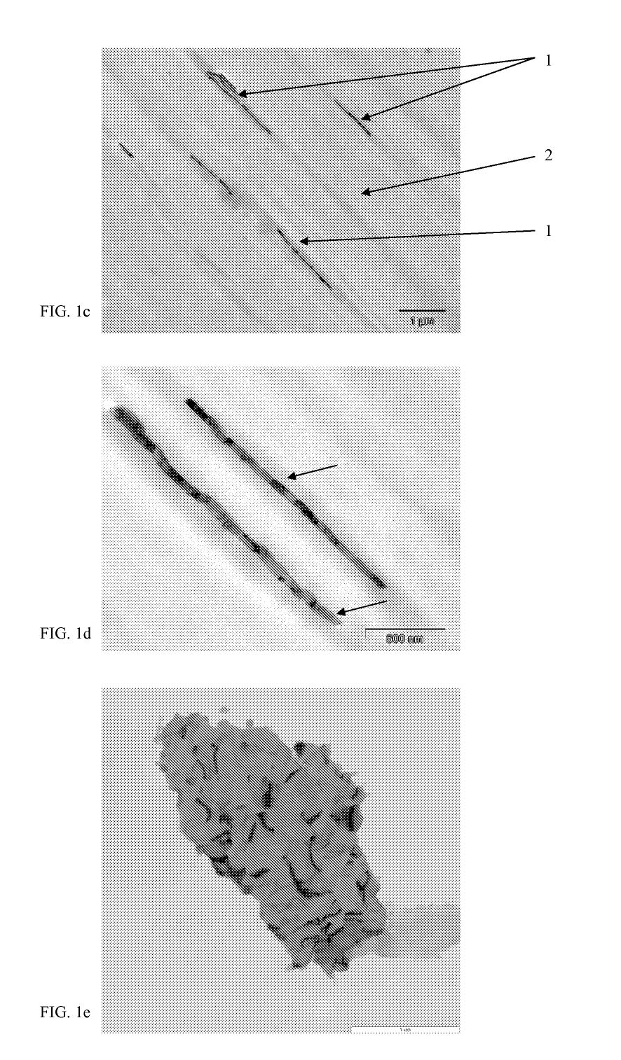

As shown in FIGS. 1a, 1b, 1c, 1d, and 1e, the aluminium particles, denoted by reference 1, are in the form of lamellae, predominantly roughly rectangular (cf. FIG. 1e), embedded in the PET 2 matrix and arranged as several lamellae parallel to faces 3 and 4 of film 5 (cf. FIG. 1b).
The distribution of the particles in the various films as well as their size are estimated by optical measurements using a light microscope of the NIKON® type. The aluminium particles are randomly distributed in the plane of the PET film prepared by the addition of ground material derived from recycled metallized polymer films. The form factor (F), defined as the ratio of the largest dimension in the plane of the particle (L) to its thickness (e), is in this example approximately 100 (see FIG. 1d: F=1250 nm/12.5 nm).

5. Determination of the Aluminium Filler in the Films

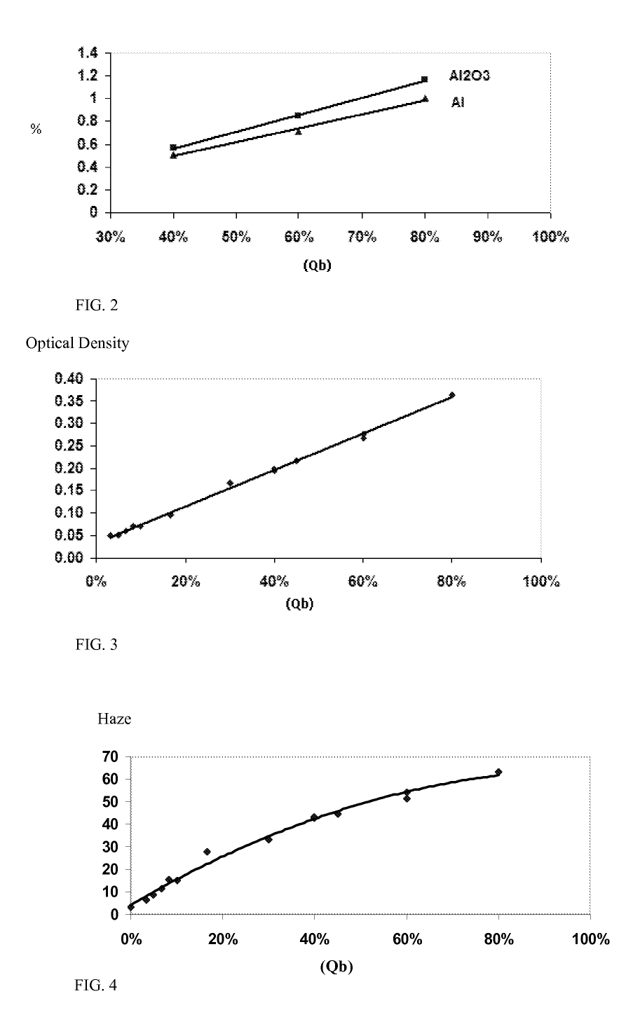

The presence of aluminium is quantified by X-ray fluorescence measurements. The content of aluminium oxide, for example Al₂O₃, is then calculated, the values obtained being in agreement with theoretical expectations (see FIG. 2).
The presence of aluminium is demonstrated by so-called ash content measurements. The ash content is measured after complete combustion for various films containing ground material. For a film that only contains PET filled with silica particles, the value of 0.11% corresponds to the quantity of silica used. For a film that contains 80% ground material the total ash content (aluminium and silica) is 1.11%, leading to a percentage of aluminium of 1% (see FIG. 2).

6. Specific Optical Properties of Biaxially Oriented Filled PET Films

The optical properties of PET films containing ground material are highly dependent on the concentration of the incorporated product. A satin-grey appearance is obtained at high concentrations (≧60% as an example) whereas an appearance identical to a standard PET film is obtained for a concentration below a known threshold.

6.1. Optical Density

The optical density OD is measured using a densitometer of the MACBETH® type according to ASTM D-1003, an apparatus for measuring the luminous intensity (orthochromatic source, wavelength range from 350 to 650 nm) transmitted through a film. For a biaxially stretched film with a thickness of approximately 12 μm, the optical density increases from 0.04 for 0% of ground material to 0.45 for 100% of ground material in the bulk of the film (see FIG. 3).

6.2. Haze

Haze is measured using a hazemeter of the BYK GARDNER® type according to ASTM D-1003. Haze is determined by the fillers within the film, by the void created around the fillers during stretching, by the surface roughness and by the ground material incorporated. As an example, a biaxially stretched film that contains 80% ground material with a thickness of 12 μm, has a very high haze (≧60%, see FIG. 4) relative to a PET film without addition of ground material (haze ˜3%).

6.3. Colorimetry

The colorimetric measurements of the type L*, a*, b*, and the whiteness index WI ASTM E-313 are carried out using a spectrophotometer of the KONICA-MINOLTA® type. On increasing the quantity of ground material incorporated in the biaxially stretched film, the luminosity and the whiteness index decrease, and the films become increasingly grey (see FIGS. 5a and 5b).

6.4. Gloss

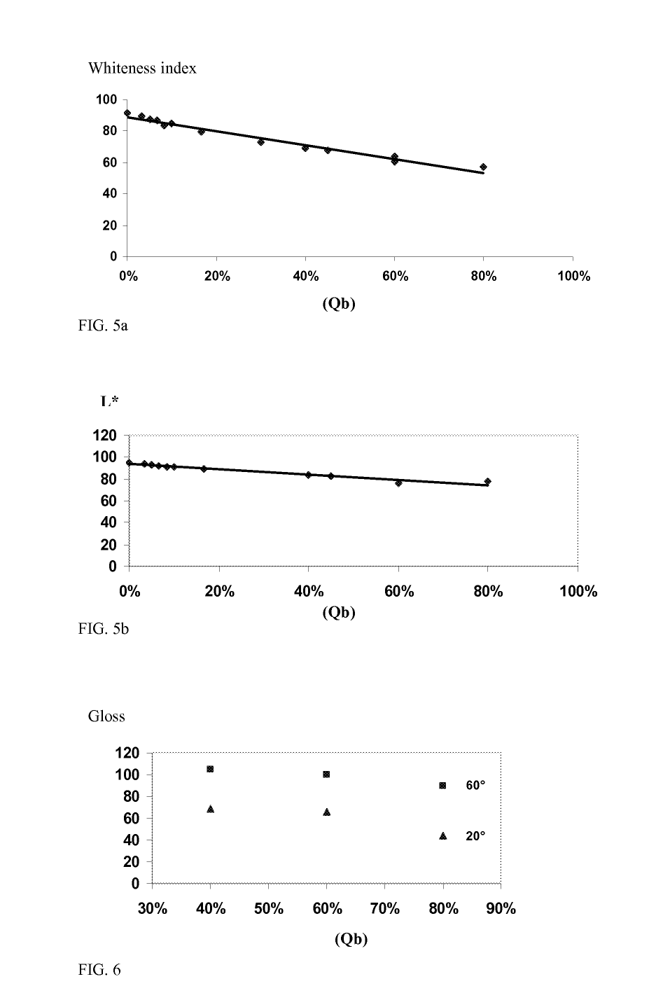

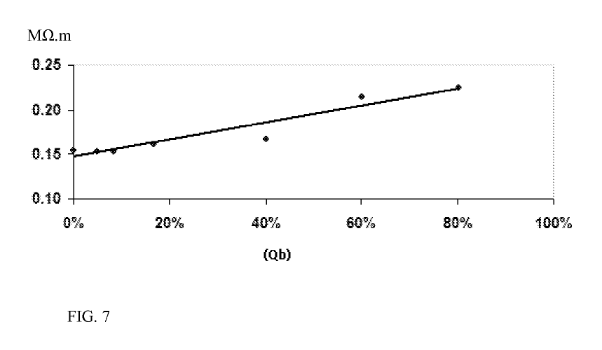

Gloss is measured using a reflectometer of the GARDNER MIRROR-TRI-GLOSS® type according to ASTM D-2457. The surface of the sample is subjected to a light beam at a defined angle (here 20° and 60°) and the light reflected is measured photoelectrically. A PET film with 60% of ground material is appreciably less glossy than a film with 40% of ground material (see FIG. 6).

7. Specific Surface Properties of Biaxially Oriented Filled PET Films

7.1. Surface Tension/Wettability

Surface tension is measured using calibrated inks according to test method ASTM D-2578. A film containing 80% of ground material has a surface tension of 54 mN/m, which is higher than the surface tension of a standard PET (48 mN/m). This can determine better printability depending on the case.

7.2. Coefficient of Friction/Slip

The coefficient of friction is measured using apparatus of the INSTRON® type according to ASTM D-1894. The addition of ground material improves the slip of the film and consequently its machinability.

8. Electrical Behaviour of Biaxially Oriented Filled Pet Films

The various films considered in these examples are not antistatic, as the surface resistivity measured according to ASTM D-257 with a resistivity meter of the KEITHLEY® type (electrometer) is greater than 10¹⁵ Ω/square.
The melt resistivity measured according to the method described below increases if the percentage of ground material increases (see FIG. 7).

### Measurement of the Resistivity of Polymers in the Molten State

The field of application of this method of measurement only includes molten polymers. The principle is measurement of the intensity of the current passing through a sheet defined by approximately ten granules of polymer in the molten state, after stoving under vacuum, on subjecting them to a defined voltage.

The instrument is based on the following equations from physics:

U=RI

R=rho*L/S

Therefore rho=R*S/L=(U/I)*(S/L)

### Where

Q=cross-section of the polymer sheet
L=length of the polymer sheet
E=thickness of the dielectric
S=area of polymer analysed
U=voltage (V)
I=current intensity (A)

### Moreover, S=Q*E

We therefore have: rho=K/I

Where K=U*S/L

The following procedure is used for the measurement:
dry 100 g of polymer granules in a stove under vacuum, 2 hours at 140° C.,
prepare the heating unit of the electrometer 1 hour beforehand, at 278° C.,
leave the 10 polymer granules taken from the 100 grams of dry granules, for at most 5 minutes in the measuring cell, but wait long enough for melting to be effective,
apply the voltage and measure the current.
   Based on the design of the electrometer, it is found that:

Rho=0.142/Intensity recorded in MΩ·metre

9. Behaviour of Biaxially Oriented Filled Pet Films with Respect to Adhesion of a Thin Metallic Layer

9.1. A PET film containing 60% of ground material in its bulk is metallized by vacuum evaporation (thickness of the metallic layer ˜20 nm). The adhesion strength of the metal (in this case aluminium) on polyester film is measured according to the AIMCAL recommendations TP-105-92 (“Metallizing Technical Reference” published by the Association of Industrial Metallizers, Coaters and Laminators). The adhesion strength between the metallic layer and the PET film is 0.2 N/38 mm. The adhesion strength between one and the same type of metallic layer and a standard PET film is approximately 0.05 N/38 mm. The adhesion strength between the same type of metallic layer and a plasma-treated PET film is approximately 0.15 N/38 mm.

9.2. A PET film containing 60% of ground material in a coextruded layer is metallized by vacuum evaporation (thickness of the metallic layer ˜20 nm). The adhesion strength of the metal (in this case aluminium) on polyester film is measured according to the test method described above. The adhesion strength between the metallic layer and the PET film is 0.2 N/38 mm. The adhesion strength between the same type of metallic layer and a plasma-treated PET film is approximately 0.15 N/38 mm. The adhesion strength between the same metallic layer and a standard PET film is approximately 0.05 N/38 mm.

10. Behaviour of Biaxially Oriented Filled Pet Films with Respect to Surface Treatment

10.1. The surface of a film containing 60% ground material is treated with an electric discharge of the corona type. The treatment conditions are: atmospheric pressure (1 bar), treatment gas ambient air, film-electrode gap ˜1 mm, dose 15 Wmin/m². Then the surface tension of the film is measured using calibrated test inks according to test method ASTM D-2578. The surface tension of the film increases from 52 mN/m to 58 mN/m.

10.2. The surface of a film containing 60% ground material is treated with a plasma of the magnetron type under vacuum. The pressure is 5×10⁻² mbar, the treatment gas is a mixture of Ar and O₂, the film-electrode gap is approximately 20 cm and the speed of movement of the film is 600 m/min. Then the surface energy of the film is measured using calibrated test inks according to ASTM D-2578. The surface energy of the film increases from 52 mN/m to more than 60 mN/m.

10.3. The surface of a film containing 60% ground material is treated with a dielectric barrier discharge plasma. The pressure is atmospheric pressure (1 bar), the treatment gas is a nitrogen-based mixture, the film-electrode gap is approximately 1 mm, the dose is 20 Wmin/m². Then the surface energy of the film is measured using calibrated test inks according to ASTM D-2578. The surface energy of the film increases from 52 mN/m to more than 60 mN/m, demonstrating a change in the physicochemical nature of the surface of the film.

11. Particular Mechanical Properties (Ease of Linear Propagation of Tearing) of the Biaxially Oriented Filled PET Films

Measurements of MD/TD breaking strength (TD corresponding to the transverse direction and MD corresponding to the machine direction) and of MD/TD elongation at break are carried out according to ASTM D-882 using an instrument of the INSTRON® type and show that the mechanical properties in the two directions are lower than in the case of a PET without the addition of ground material. Measurements of puncture resistance are in agreement. Measurements of oriented tearing carried out using an instrument of the ELMENDORF® type show that the incorporation of ground material (particles) facilitates linear propagation of tearing.

12. Oxygen and Water Vapour “Barrier” Properties of the Biaxially Oriented Filled PET Films

The values of permeability to oxygen measured according to ASTM D-3985 and to water vapour measured according to ASTM F-1249 are not in any way degraded relative to a standard PET for the same thickness.

13. Fire Resistance of the Biaxially Oriented Filled PET Films

Biaxially oriented PET films containing said ground material and having a thickness of 23 μm are evaluated with respect to their fire resistance according to standard UL94. A film filled with ground material (Qb) at 80 wt. % does not ignite and does not drip.

14. Microwave Cooking Test in the Presence of a Filled Film

Cooking tests are carried out on various food products to evaluate whether packaging that includes films containing said ground material have the necessary properties for applications of the “susceptor” type, for which there is considerable demand in the field of active packaging. The equipment used is a microwave oven of the DAEWOO® type, which has an output power of approximately 900 W and operates at the standard industrial frequency of 2.45 GHz. The cooking time is adjusted depending on the type of food and packaging. For example, a PET film containing 80% of ground material (Qb) proves particularly suitable for cooking poultry, obtaining browning corresponding to conventional cooking. It is also significant that the behaviour of films filled with metal particles in the bulk is clearly improved during a longer time of exposure to microwaves compared with the behaviour of surface-metallized films of comparable optical density (films of the “susceptor” type that are usually used).

TABLE 2
Microwave cooking test in the presence
of a film containing ground material.
Appearance and texture

| | Box | | Bag | |
|---|---|---|---|---|
| Reference film | Hamburger | Nuggets | Chicken | Nuggets |
| PET LUMIRROR ® | □ | □ | X | X |
| control | | | | |
| PET with 80% of | □ | □ | □ | X |
| ground material (Qb) | | | | |

X: poor
□: correct
◯: good

### II—Examples of the Production of Films of Polypropylene Filled with Lamellar Particles of Aluminium

1. Preparation of the Ground Material Based on Metallized Polypropylene

After being ground in an ALPINE® grinding mill from HOSOKAWA® (stage A), PET films metallized with aluminium (CLARYL® range from TORAY®) are processed on a machine of the VACUREMA® type from EREMA®.
Next, the films reduced to flakes are compacted and agglomerated in a compactor at 133° C. (stage B). Then the agglomerates are melted at 190° C. (stage C). The molten mass is then cooled and solidified in a stream of water at ambient temperature (stage D) by means of equipment associated with the VACUREMA® machine, with the brand name RIETER®. Said cooled mass is cut at ambient temperature into granules by the device downstream of the RIETER® equipment (stage E).
The characteristics and operating conditions of grinding, agglomeration and extrusion (stages A-E) are as follows:

### Characteristics and Operating Conditions of the Compactor

Motor power: 60 KW
Compacting speed: 145 rpm
Machine loading: 51%
Level of vacuum: 36 mbar
Temperature of the granules in the compactor: 133° C.
Temperature of the zone at the level of the filling hole of the extruder: 155° C.

### Conditions of Vacuum Extrusion

Flow rate: 946 kg/hour
Screw speed: 64 rpm
Machine loading: 48%
Level of vacuum: 20 mbar
Filtration is ensured by 4 metal filters with a “cut-off” of 35 microns. Neither filter clogging nor deposits are found on dismantling.

2. Preparation of Polypropylene Films Containing Said Ground Material

Next, the granules obtained as above, called ground material, are extruded mixed with other polymers in the film-making machine (stage F) in order to develop new films of polypropylene filled with lamellar particles of aluminium with percentages of ground material Qb less than or equal to 100.
The various mixtures based on polypropylene and ground material are homogenized in the granulated state and are then extruded in the molten state through a slot die as a thick film, which is cooled on a succession of three drums cooled to a temperature of approximately 20° C. (stage G) so as to form an amorphous film.

3. Preparation of Biaxially Oriented Polypropylene Films Containing Said Ground Material

The amorphous film thus obtained is then subjected to longitudinal stretching MD (degree LS 4.0) followed by transverse stretching (degree TS 4.5) (stage H). The degree of planar stretching (defined as the product of the degree of longitudinal stretching and the degree of transverse stretching, regardless of the order thereof) is 18. The biaxially stretched film, with a thickness of 18 μm, is then subjected to heat-setting at a temperature above 130° C. (stage I).

1. A polyester or polyolefin film comprising lamellar particles based on at least one of a metal and a metal oxide, the film obtained by extruding a raw material comprising a material ground from at least one coated film, the coated film comprising at least one of a polyester film and polyolefin film and at least one coating film based on at least one of the metal and the metal oxide.

2. The film according to claim 1, wherein the lamellar particles correspond to a form factor (F=L/e) defined as the ratio of the largest dimension (L) in the plane of the particle to its thickness (e), wherein 10≦F≦1000.

3. The film according to claim 2, wherein 50≦F≦500.

4. The film according to claim 2, wherein F is sub-micrometric.

5. The film according to claim 1, comprising a content Tx (in wt. %) of lamellar particles of 10⁻³≦Tx<10.

6. The film according to claim 5, wherein 10⁻²≦Tx≦5.

7. The film according to claim 1, wherein the metal is selected from the group consisting of aluminium, copper, nickel, gold, silver, and alloys thereof, and wherein the metal oxide is selected from the group consisting of oxides of any selected metal, oxides of silicon, and mixtures thereof.

8. The film according to claims 1, wherein the coated film from which the ground material is derived comprises recyclable coated film.

9. The film according to claims 1, wherein the coated film is waste coated film.

10. The film according to claim 1, wherein the raw material comprises a content Qb (in wt. %) of the ground material of 20≦Qb≦100.

11. The film according to claim 10, wherein 25≦Qb≦99.

12. The film according to claim 10, wherein 30≦Qb≦95.

13. The film according to claim 1, wherein the raw material comprises a content Qb (in wt. %) of the ground material of 10⁻¹≦Qb≦20.

14. The film according to claim 13, wherein 1≦Qb≦20.

15. The film according to claim 13, wherein 30≦Qb≦20.

16. The film according to claim 1, wherein the film is isotropic biaxially stretched, tensilized biaxially stretched, or balanced biaxially stretched.

17. The film according to claim 1, wherein the film has a thickness (e) between 3 and 350 μm.

18. The film according to claim 17, wherein the thickness (e) is between 8 and 50 μm.

19. The film according to claim 17, wherein the thickness (e) is between 8 and 36 μm.

20. The film according to claim 1, wherein the film further comprises at least one coating on at least one face, the coating provided by a method selected from the group consisting of coextrusion, coating, extrusion coating, corona treatment under ambient air or gases, vacuum evaporation, plasma treatment and physicochemical vacuum deposition.

21. A method for producing a raw material suited for use in manufacture of a coated film, the method comprising the steps of:
A. grinding at least one coated film that comprises at least one of a polyester film and a polyolefin film and at least one coating film based on at least one of a metal and a metal oxide to obtain flakes;
B. optionally compacting the flakes to form agglomerates;
C. melting the flakes or agglomerates to form a molten mass;
D. optionally removing from the molten mass the metal or metal oxide having a largest dimension (L) greater than or equal to 3 μm;
E. solidifying the molten mass; and
F. granulating the solidified mass.

22. A method for producing a polyester or polyolefin film comprising lamellar particles based on at least one of a metal and a metal oxide, the method comprising the steps of:
A. grinding at least one coated film that comprises at least one of a polyester film and a polyolefin film and at least one coating film based on at least one of a metal and a metal oxide to obtain flakes;
B. optionally compacting the flakes to form agglomerates;
C. melting the flakes or agglomerates to form a molten mass;
optionally removing from the molten mass the metal or metal oxide having a largest dimension (L) greater than or equal to 3 μm;
E. solidifying the molten mass;
F. granulating the solidified mass to form discrete elements;
G. melt extruding a mixture containing a quantity Qb (in wt. %) of the discrete elements to produce the film comprising lamellar particles; and
H. cooling the film comprising lamellar particles.

23. The method according to claim 22, further comprising the steps of:
I. longitudinal and transverse stretching of the film comprising lamellar particles; and
J. heat-setting of the film comprising lamellar particles,
wherein when the film comprises polyester, the heat-setting is accomplished at a suitable temperature at or above 150° C., and when the film comprises polyolefin, the heat-setting is accomplished at a suitable temperature at or above 120° C.

24. The method according to claim 23, wherein the film comprises polyester and the heat-setting is accomplished at a temperature between 180° C. and 250° C.

25. The method according to claim 24, wherein the heat-setting is accomplished at 240° C.

26. The method according to claim 23, wherein the film comprises polyolefin and the heat-setting is accomplished at a temperature between 130° C. and 200° C.

27. The method according to claim 26, wherein the heat-setting is accomplished at 150° C.
